(19) United States
(12) Patent Application Publication
(10) Pub. No.: US 2024/0053410 A1
(43) Pub. Date: Feb. 15, 2024

(54) ENERGY BASED TASK SHIFTING

(71) Applicant: Apple Inc., Cupertino, CA (US)

(72) Inventors: Cyril de la Cropte de Chanterac, San Francisco, CA (US); Lawrence A. Cayton, Seattle, WA (US); Brian C. Beer, San Francisco, CA (US); Shardul S. Mangade, Santa Clara, CA (US); Farman A. Syed, San Jose, CA (US); Andrea R. Romano, San Francisco, CA (US)

(21) Appl. No.: 17/819,771

(22) Filed: Aug. 15, 2022

(51) Int. Cl. G01R 31/396; G01R 31/367

(52) U.S. Cl. CPC G01R 31/396; G01R 31/367

(57) ABSTRACT

An electronic device can include a processor programmed to detect connection of an external power source to the electronic device, determine an estimated disconnection time at which the external power source is expected to be disconnected from the electronic device, analyze power grid data corresponding to the external power source to identify one or more desired background processing intervals and one or more undesired background processing intervals prior to the estimated disconnection time, and perform background processing during the identified one or more desired battery charging intervals and inhibit background processing during the one or more undesired battery charging intervals. The processor can be programmed to determine an estimated disconnection time using a machine learning model. The processor can be programmed to inhibit background processing by reducing the amount of background processing during certain undesired background processing intervals or by preventing background processing during certain undesired background processing intervals.

### BACKGROUND

Electronic devices may perform tasks that are not time critical. For example, users of battery-powered electronic devices may plug them in to recharge overnight, even though the amount of time required to charge the battery is less than the amount of time that the device will be plugged in. Similarly, electronic devices may perform background tasks that are not time critical.

### SUMMARY

In some cases it may be desirable to shift non-time-critical tasks performed by an electronic device, including for example battery charging and/or background processing, to certain time windows depending upon characteristics of a power source connected to the electronic device.

An electronic device can include a processor programmed to detect connection of an external power source to the electronic device, determine an estimated disconnection time at which the external power source is expected to be disconnected from the electronic device, analyze power grid data corresponding to the external power source to identify one or more desired background processing intervals and one or more undesired background processing intervals prior to the estimated disconnection time, and perform background processing during the identified one or more desired battery charging intervals and inhibit background processing during the one or more undesired battery charging intervals. The processor can be programmed to determine an estimated disconnection time using a machine learning model. The processor can be programmed to inhibit background processing by reducing the amount of background processing during certain undesired background processing intervals or by preventing background processing during certain undesired background processing intervals.

The processor can be further programmed to retrieve the power grid data corresponding to the external power source from a grid data server. The power grid data corresponding to the external power source can include carbon intensity data. The one or more desired background processing intervals can be intervals of lower carbon intensity, and the one or more undesired background processing intervals can be intervals of higher carbon intensity. The power grid data corresponding to the external power source can include cost data. The one or more desired background processing intervals can be intervals of lower cost, and the one or more undesired background processing intervals are intervals of higher cost.

The electronic device can further include a display. The processor can be further programmed to communicate information about the one or more desired background processing intervals or the one or more undesired background processing intervals to a user via the display. The electronic device can further include an input device. The processor can be further programmed to receive user input regarding background processing via the input device.

A method of operating an electronic device, performed by a processor of the electronic device, can include detecting connection of an external power source to the electronic device, determining an estimated disconnection time at which the external power source is expected to be disconnected from the electronic device, analyzing power grid data corresponding to the external power source to identify one or more undesired background processing intervals prior to the estimated disconnection time, and inhibiting background processing during the identified one or more desired battery charging intervals. The processor can be programmed to determine an estimated disconnection time using a machine learning model. The processor can be programmed to inhibit background processing by reducing the amount of background processing during certain undesired background processing intervals or by preventing background processing during certain undesired background processing intervals.

The processor can be further programmed to retrieve the power grid data corresponding to the external power source from a grid data server. The power grid data corresponding to the external power source can include carbon intensity data. The one or more desired background processing intervals can be intervals of lower carbon intensity, and the one or more undesired background processing intervals can be intervals of higher carbon intensity. The power grid data corresponding to the external power source can include cost data. The one or more desired background processing intervals can be intervals of lower cost, and the one or more undesired background processing intervals can be intervals of higher cost.

The method can further include communicating information about the one or more desired background processing intervals or the one or more undesired background processing intervals to a user via a display of the electronic device. The method can further include receiving user input regarding background processing via an input device of the electronic device.

### BRIEF DESCRIPTION OF THE DRAWINGS

FIG. 1 illustrates a block diagram of an electronic device.

FIG. 2 illustrates an optimized battery charging routine for an electronic device.

FIG. 3 illustrates an optimized battery charging routine for an electronic device that adapts battery charging to grid conditions.

FIG. 4 illustrates a flowchart of an optimized battery charging routine for an electronic device that adapts battery charging to electrical grid conditions.

FIG. 5 illustrates a system including an electronic device implementing an optimized battery charging routine that adapts to electrical grid conditions along with external data sources that inform the optimized battery charging routine.

FIG. 6 illustrates an electronic device that communicates parameters of an optimized battery charging routine to a user.

FIG. 7 illustrates a background processing optimization routine for an electronic device that adapts background processing to grid conditions.

FIG. 8 illustrates a flowchart of a background processing adaptation routine for an electronic device that adapts background processing to electrical grid conditions.

### DETAILED DESCRIPTION

In the following description, for purposes of explanation, numerous specific details are set forth to provide a thorough understanding of the disclosed concepts. As part of this description, some of this disclosure's drawings represent structures and devices in block diagram form for sake of simplicity. In the interest of clarity, not all features of an actual implementation are described in this disclosure. Moreover, the language used in this disclosure has been selected for readability and instructional purposes, has not been selected to delineate or circumscribe the disclosed subject matter. Rather the appended claims are intended for such purpose.

Various embodiments of the disclosed concepts are illustrated by way of example and not by way of limitation in the accompanying drawings in which like references indicate similar elements. For simplicity and clarity of illustration, where appropriate, reference numerals have been repeated among the different figures to indicate corresponding or analogous elements. In addition, numerous specific details are set forth to provide a thorough understanding of the implementations described herein. In other instances, methods, procedures, and components have not been described in detail so as not to obscure the related relevant function being described. References to “an,” “one,” or “another” embodiment in this disclosure are not necessarily to the same or different embodiment, and they mean at least one. A given figure may be used to illustrate the features of more than one embodiment, or more than one species of the disclosure, and not all elements in the figure may be required for a given embodiment or species. A reference number, when provided in a drawing, refers to the same element throughout the several drawings, though it may not be repeated in every drawing. The drawings are not to scale unless otherwise indicated, and the proportions of certain parts may be exaggerated to better illustrate details and features of the present disclosure.

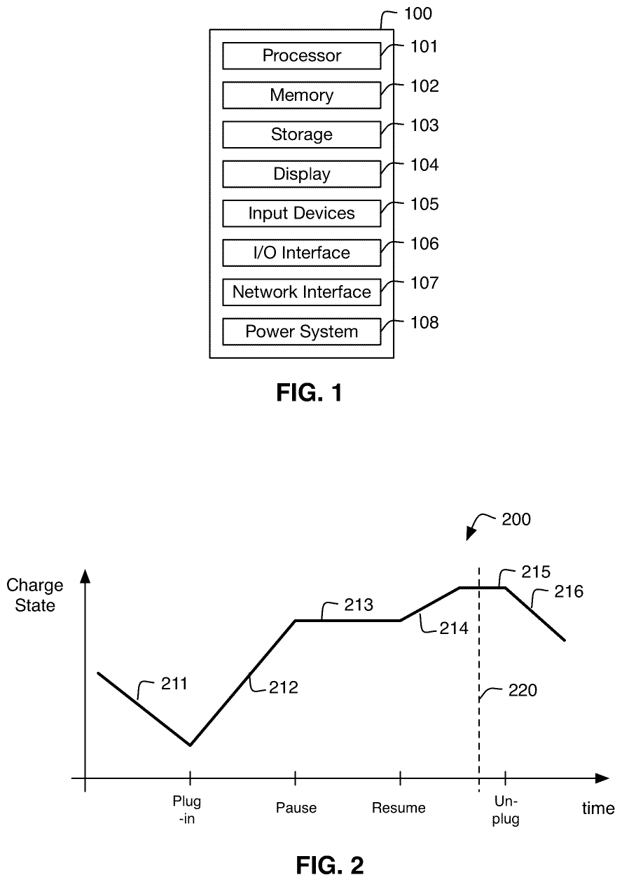

FIG. 1 is a block diagram of an electronic device 100, according to embodiments of the present disclosure. The electronic device 100 may include, among other things, one or more processors 101 (collectively referred to herein as a single processor for convenience, which may be implemented in any suitable form of processing circuitry), memory 102, nonvolatile storage 103, a display 104, input devices 105, an input/output (I/O) interface 106, a network interface 107, and a power system 108. The various functional blocks shown in FIG. 1 may include hardware elements (including circuitry), software elements (including machine-executable instructions), or a combination of both hardware and software elements (which may be referred to as logic). The processor 101, memory 102, the nonvolatile storage 103, the display 104, the input devices 105, the input/output (I/O) interface 106, the network interface 107, and/or the power system 108 may each be communicatively coupled directly or indirectly (e.g., through or via another component, a communication bus, a network, etc.) to one another to transmit and/or receive data amongst one another. It should be noted that FIG. 1 is merely one example of a particular implementation and is intended to illustrate the types of components that may be present in the electronic device 100.

By way of example, the electronic device 100 may include any suitable computing device, including a desktop or laptop/notebook computer (such as a MacBook®, MacBook® Pro, MacBook Air®, iMac®, Mac® mini, or Mac Pro® available from Apple Inc. of Cupertino, California), a portable electronic or handheld electronic device such as a wireless electronic device or smartphone (such as an iPhone® available from Apple Inc. of Cupertino, California), a tablet computer (such as an iPad® available from Apple Inc. of Cupertino, California), a wearable electronic device (such as an Apple Watch® by Apple Inc. of Cupertino, California), and other similar devices.

Processor 101 and other related items in FIG. 1 may be embodied wholly hardware or by hardware programmed to execute suitable software instructions. Furthermore, the processor 101 and other related items in FIG. 1 may be a single contained processing module or may be incorporated wholly or partially within any of the other elements within the electronic device 100. Processor 101 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. Processor 101 may include one or more application processors, one or more baseband processors, or both, and perform the various functions described herein.

In the electronic device 100 of FIG. 1, processor 101 may be operably coupled with a memory 102 and a nonvolatile storage 103 to perform various algorithms. Such programs or instructions executed by processor 101 may be stored in any suitable article of manufacture that includes one or more tangible, computer-readable media. The tangible, computer-readable media may include the memory 102 and/or the nonvolatile storage 103, individually or collectively, to store the instructions or routines. The memory 102 and the nonvolatile storage 103 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by processor 101 to enable the electronic device 100 to provide various functionalities.

In certain embodiments, the display 104 may facilitate users to view images generated on the electronic device 100 In some embodiments, the display 104 may include a touch screen, which may facilitate user interaction with a user interface of the electronic device 100. Furthermore, it should be appreciated that, in some embodiments, the display 104 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input devices 105 of the electronic device 100 may enable a user to interact with the electronic device 100 (e.g., pressing a button to increase or decrease a volume level). The I/O interface 106 may enable electronic device 100 to interface with various other electronic devices, as may the network interface 107. In some embodiments, the I/O interface 106 may include an I/O port for a hardwired connection for charging and/or content manipulation using a standard connector and protocol, such as the Lightning connector provided by Apple Inc. of Cupertino, California, a universal serial bus (USB), or other similar connector and protocol. The network interface 107 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, long term evolution (LTE®) cellular network, long term evolution license assisted access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 107 may include, for example, one or more interfaces for using a cellular communication standard of the 5G specifications that include the millimeter wave (mmWave) frequency range (e.g., 24.25-300 gigahertz (GHz)) that defines and/or enables frequency ranges used for wireless communication. The network interface 107 of the electronic device 100 may allow communication over the aforementioned networks (e.g., 5G, Wi-Fi, LTE-LAA, and so forth).

The network interface 107 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

The power system 108 of the electronic device 100 may include any suitable source of power, such as a rechargeable battery (e.g., a lithium ion or lithium polymer (Li-poly) battery) and/or a power converter, including a DC/DC power converter, an AC/DC power converter, a power adapter (which may be external), etc.

FIG. 2 illustrates an optimized battery charging routine for an electronic device. More specifically, FIG. 2 illustrates a plot 200 of battery state of charge on the vertical axis versus time on the horizontal axis. Various events in the charging sequence are identified as times on the time axis. For example, prior to the device being plugged in to an external power source (such as mains power, an external battery pack, a car accessory adapter, etc.), the battery may be discharging as indicated by curve segment 211. After the device is plugged in to the external power source, the battery can begin charging as indicated by curve segment 212. Upon being plugged in to the external power source, the device can determine an estimated disconnect time 220 at which it expects to be disconnected from the external power source, which can be used to intelligently adapt the charging sequence as described in greater detail below.

The determination of estimated disconnect time 220 can be made in various ways based on sensor inputs (e.g., time of day, location, etc.) and a machine learning model or other program structure that accounts for prior activity or otherwise infers a likely disconnect time. For example, if a user typically plugs in a device at home at around 10 μm and unplugs it around 6 am, the device can infer that—if it is plugged in at around 10 pm at the user's home location—it will remain on the charger until about 6 am and can thus adapt the charging sequence accordingly. The same would be true if a user plugs in at the user's work location around 8 am and unplugs around 12 pm, which could allow the system to infer that the user is typically at his desk at this time. The inferences can be based on inputs other than time and location. For example, if a user plugs in and the device can detect that it is moving at a relatively high rate of speed, the device might infer that it is in an automobile. Depending on the particular implementation of the machine learning model or other program structure, more or less detailed inferences may be derived. In any case, the inference may be used to modify the charging sequence as follows.

In the first example of the preceding paragraph, in which the device infers that it is at the user's home location and has been plugged in at around 10 pm, the device can assume that it will remain connected to mains power until about 6 am. Thus, the device does not need to charge at the maximum rate (represented by the slope of curve segment 212) to reach full charge as soon as possible. In fact, it may be desirable to slow the rate of charging and/or pause charging for a time period, depicted by curve segment 213 to delay reaching full charge of the battery. For example, a battery's useful life (i.e., battery health or number of charge cycles over which substantially full capacity can be maintained) may be extended by reducing the amount of time that the battery spends at full charge. Thus, in the optimized battery charging example of FIG. 2, battery charging may be paused during interval 213.

Estimated disconnect time 220 may be further used by the device to resume charging at a time selected to ensure that the battery reaches a fully charged state (represented by charge level/curve segment 215) prior to estimated disconnect time 220. This resumed charging is represented by curve segment 214. This charging segment may take place at a reduced rate, for example because the battery is closer to full charge, as indicated by the reduced slope of resumed charging segment 214 versus original charging segment 212. In any case, the machine learning model or other program structure that controls the optimized battery charging sequence may account for the expected charging rate and estimated disconnect time to ensure that the battery is fully charged prior to the user disconnecting the device from the external power source. This may be accomplished by selecting an estimated disconnection time that is before the likely or typical disconnect time and/or by ensuring that the battery is fully charged before estimated disconnect time 220. Once the user disconnects the device from the external power source, the battery may begin discharging, as illustrated by curve segment 216.

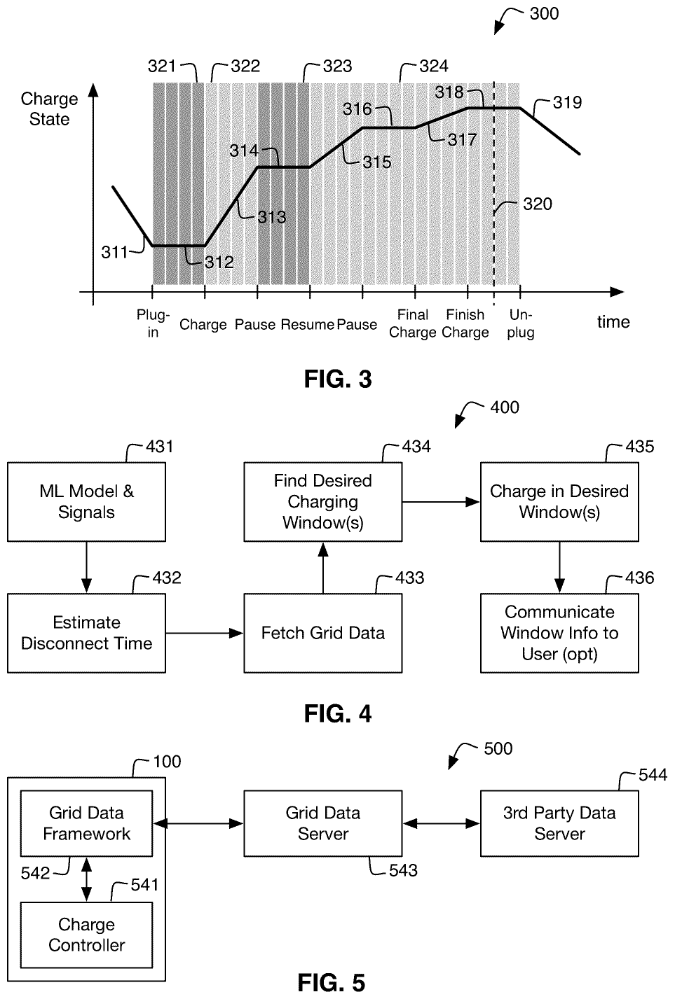

The optimized battery charging technique described with respect to FIG. 2 is “optimized” in the sense that it may improve battery health by reducing the amount of time that the battery spends at a full charge state. FIG. 3 illustrates an optimized battery charging routine for an electronic device in which the “optimization” may further adapt battery charging to “grid conditions.” In one embodiment, the grid conditions can include a carbon emission property of the power grid. In many areas the relative proportion of higher carbon power sources versus lower carbon power sources may vary throughout the day. For example, in areas that have solar grid power available, there may be a greater fraction of solar power available during the day versus night, when the grid may rely more heavily on fossil fuel power. In some areas with wind power, there may be more wind power available at night, meaning that there may be a greater reliance on fossil fuel power during the day. As a result, the carbon intensity of the mains power supply derived from the grid can vary. If present and/or forecasted carbon intensity data is available to the device, the optimized battery charging routine can adapt battery charging based on whether the current makeup of the grid supplied mains power is relatively low carbon or relatively high carbon.

In some applications, the “grid conditions” may be based on properties of the supplied power other than grid carbon intensity. For example, a user may have some sort of local power generation capability other than or in addition to the grid-supplied power, such as a solar power system, a local wind power system, a geothermal generation system, a battery system, etc. In those cases, the device may can obtain data from these local power generation sources to adapt the optimized charging routine. Although the following description is primarily in terms of adapting battery charging to grid conditions in the form of current and/or forecasted carbon intensity, such a system may advantageously adapt battery charging to any of a variety of properties of the supplied power whether supplied from a power grid or other more localized source.

FIG. 3 illustrates an optimized battery charging routine for an electronic device that can further adapt to grid conditions. More specifically, FIG. 3 illustrates a plot 300 of battery state of charge on the vertical axis versus time on the horizontal axis. Various events in the charging sequence are identified as times on the time axis. For example, prior to the device being plugged in to an external power source (mains power, in this example), the battery may be discharging as indicated by curve segment 311. At some point in time, the device can obtain grid condition data. This point in time can be before, when, or after the device is plugged in. The device may receive updated grid condition data periodically, and it may be advantageous for the data to be relatively recent to more accurately inform the adaptive charging techniques described below. As one example, the grid condition data may include carbon intensity data as described above. In some cases, this data may correspond to different time intervals as indicated by vertical bars 321/322/323/324 in FIG. 3. Additionally, the device may analyze the grid data to determine time windows during which battery charging should be performed or paused. For example, it may be desirable to forego charging during time windows when the carbon intensity (or other grid data) indicates that charging would be less favorable. (Another example could be a system with a variable rate tariff, in which case it may be desirable to forego charging during time periods that power is more expensive.) The process could also proceed in the reverse direction, e.g., by selecting windows during which charging is preferred. In any case, the device can determine which time windows are more preferred or less preferred for charging based on the received grid data. The device may identify such more preferred or less preferred windows to inform the optimized battery charging windows. As depicted in FIG. 3, the less preferred time intervals 321/323 (darker shading) may correspond to time periods of relatively higher carbon intensity (or other grid condition), and the more preferred time intervals 322/324 (lighter shading) may correspond to time periods of relatively lower carbon intensity (or other grid condition).

Thus, upon being plugged in to mains power, the device can determine an estimated disconnect time 320 at which it expects to be disconnected from mains power, which can be used to intelligently adapt the charging sequence. The determination of estimated disconnect time 320 can be made in various ways based on sensor inputs (e.g., time of day, location, etc.) and a machine learning model or other program structure that accounts for prior activity or otherwise infers a likely disconnect time as was described above with reference to FIG. 2. Again using the example of overnight charging, in which the device infers that it is at the user's home location and has been plugged in at around 10 pm (or other time based on previous use), the device can assume that it will remain connected to mains power until about 6 am (or other time). The device can identify certain time segments during this period during which the grid conditions are less desirable for charging, as described above. Thus, the device may not begin charging immediately upon being plugged in, as indicated by curve segment 312, as these correspond to the identified less preferred time intervals 321. Once grid conditions improve, as indicated by the received (and optionally updated) grid data, charging may begin, as indicated by curve segment 313, which corresponds to more preferred time intervals 322. Subsequently, another time window of less preferred timer intervals 323 may cause the optimized battery charging routine to pause, as indicated by curve segment 314. Charging can then resume upon improvement of grid conditions, indicated by curve segment 315 corresponding to improved grid conditions indicated by more preferred time intervals 324.

Otherwise, the adaptive charging technique depicted in FIG. 3 may proceed as described above with respect to FIG. 2. Thus, in the optimized battery charging example of FIG. 3, battery charging may be paused during the interval corresponding to curve segment 316. Battery charging may be resumed during the interval corresponding to curve segment 317 to ensure that the battery is completely charged, represented by curve segment 318) ahead of both the estimated disconnect time 320 and the actual disconnection time, upon which the battery can begin discharging, as indicated by curve segment 319.

In some operational condition, it may be desirable to inhibit or otherwise forego optimization of battery charging optimization based on grid conditions. For example, if the battery state of charge is below some discharged level threshold (e.g., below 30%, 25%, etc.), it may be desirable to begin charging immediately to ensure that power is available to the device regardless of grid conditions. Similarly, once the battery reaches a state of charge corresponding to some charged level threshold (e.g., 75%, 80%, etc.), it may be desirable to allow the battery to be fully charged just prior to the estimated disconnection time regardless of the grid conditions to ensure that the device is fully charged when disconnected by the user. Additionally, it may be preferable to only allow grid condition adaptive optimized battery charging if grid conditions are expected to improve over the predicted interval.

FIG. 4 illustrates a flowchart of an optimized battery charging routine 400 for an electronic device that adapts battery charging to electrical grid conditions. This flowchart depicts functionality that may be implemented by electronic device 100, including, for example, by processor 101, which may include one or more processors as described above. In some cases, different functions depicted in the flowchart of FIG. 4 may be implemented by different processors of a multi-processor system 100. As but one example, a processor 101 that includes a CPU, a GPU, and a NPU (neural processing unit) may use the NPU to perform certain machine learning computations. In any case, a grid condition adaptive optimized battery charging routine 400 can include a machine learning model and signal processing block 431 that can be used to detect when the electronic device is connected to an external power source and initiate the optimized charging routine as described above. These signals may include the indication of connection to an external power source as well as other signals that allow the processor to identify the power source. For example, a location signal may indicate that the device is at the user's home, workplace, or other frequently visited location, in which case it might be expected that the external power source is mains power. Alternatively, a changing location signal or a speed/velocity sensor may indicate that the device is plugged in to vehicle accessory power source. In some cases, an external power source may provide some other signal that allows it to be identified, as is often the case with wireless power transfer systems. These and other signals may be processed by a machine learning model to attempt to identify the power source and to predict a disconnect time, as indicated by block 432.

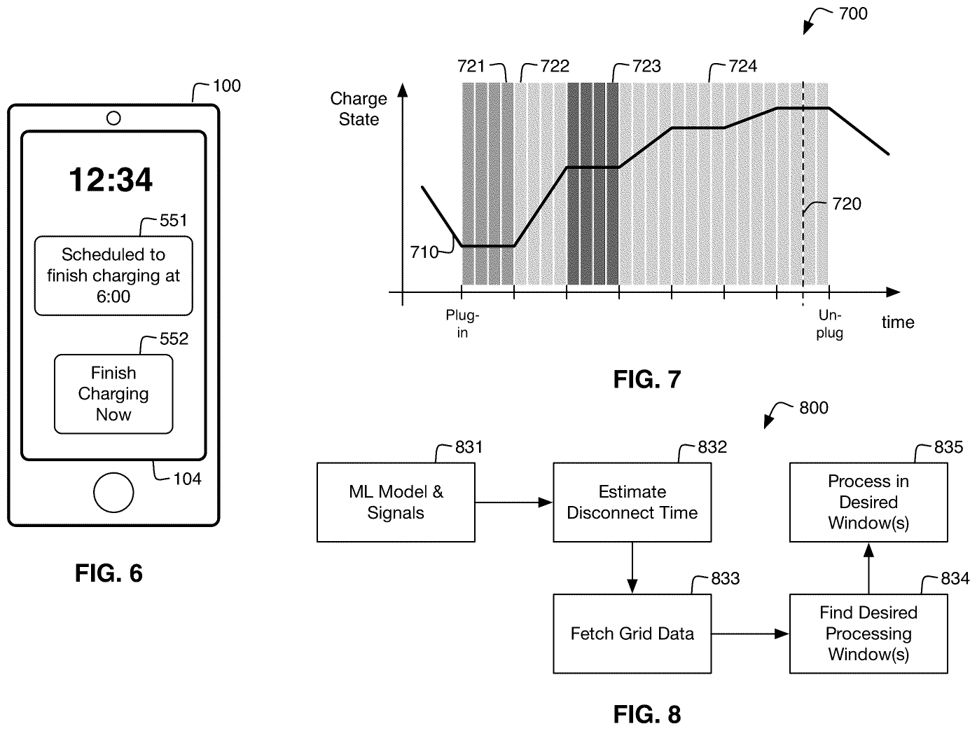

As alluded to above, the estimated disconnect time can be derived from the external signals. For example, a time signal corresponding to late evening and a location signal corresponding to a user's home along with a pattern of prior usage can be used to infer that an overnight charging cycle is beginning. Alternatively, being plugged in at an unusual time or location along with a low battery state of charge may be used to infer that the user needs the device to charge as rapidly as practicable. In cases where the estimated disconnect time provides a sufficient window for optimized charging, the processor can fetch grid data (block 433) and find desired and/or undesired charging windows (block 434), which can correspond to the more preferred time intervals 322 and less preferred timer intervals 321 discussed above. As noted above, fetching the grid data in block 433 need not occur immediately upon connecting the device to an external source, but rather can be part of an ongoing process that periodically updates both before and while connected to an external power source so that the grid data is available and/or updated as desired. Once the desired and/or undesired charging windows are identified (block 434) the processor can operate the charging system of the device to charge the battery during the desired windows and inhibit charging during the undesired windows, as depicted in block 435. In some cases, the processor can also communicate information about the charging process and the desired/undesired charging windows to the user (block 436). Examples of such communication and optional user interaction are discussed in greater detail below with respect to FIG. 6.

FIG. 5 illustrates a system including an electronic device 100 implementing an optimized battery charging routine that adapts to electrical grid conditions along with external data sources 543, 544 that can be used inform the optimized battery charging routine. More specifically, electronic device 100 can include a charge controller 541, which can be part of power system 108. The charge controller can include electronic circuitry (including analog, digital, and/or programmable circuitry) that is configured to control whether, when, and at what rate a battery of electronic device 100 is charged. It should be noted that in addition to or rather than permitting or inhibiting charging as described above, the optimized battery charging routine could also be used to control the rate at which the battery charges responsive to grid conditions. Thus, rather than inhibiting battery charging entirely during the less preferred time intervals 321, the system could be configured to slow battery charging during such intervals and increase the battery charging rate during the more preferred time intervals 322.

To accomplish this, charge controller 541 may be operatively coupled to a grid data framework 542, which can include programming structures, application programming interfaces, etc. executed by processor 101 that allow the electronic device to retrieve grid data from a grid data server 543. Grid data server 543 may be part of or associated with a device local to the user, such as a solar power system, grid battery, etc. that powers the user's home, office or other location. In other cases, the grid data server could be part of a home automation server in the user's home (or other location). In still other cases, the grid data server could be a device accessible over the Internet for providing data to one or multiple users about power conditions in their area. In some cases, grid data server 543 may obtain third party data from a third party data server 544. For example, grid data server 543 could obtain grid data for a number of grid regions from one or more third party servers 544 and provide grid data to electronic device 100 based on the present location of electronic device 100. In such case, third party servers 544 could be a server belonging to a grid regulating authority or other entity having access to carbon intensity data, pricing data, or other grid data.

FIG. 6 illustrates an electronic device 100 that communicating parameters of an optimized battery charging routine to a user. FIG. 6 illustrates electronic device 100 as a smartphone, but could in fact be any of a variety of electronic devices, such as a tablet computer, notebook or laptop computer, etc. As one example, electronic device 100 could use a display 104 to present a message 551 to the user indicating a time at which charging is scheduled to be finished. In some cases, electronic device 100 could present a control element 552, such as a UI button, that the user could use to bypass the optimized charging routine and complete charging as expeditiously as possible. In some embodiments, control element 552 and message 551 could be part of the same UI element, such as a GUI message/button, etc. In other cases, one or more other output devices of electronic device 100 could be used to provide the indication to the user and one or more other input devices of electronic device 100 could be used to receive input from the user indicating that the user wishes to bypass the optimized charging setup and complete charging as expeditiously as possible.

Message 551 could also present additional information to the user. As one example, message 551 might specifically indicate that battery charging is paused due to grid conditions and/or that battery charging is paused to optimize battery health. Additionally or alternatively, electronic device 100 can continuously monitor grid conditions and provide an indication to the user when grid conditions are more desirable for charging, such as a reduced carbon intensity, a reduced cost, availability of a preferred source, such as a local solar or grid battery system, etc. This type of communication may further be controlled with respect to the state of charge the battery as well as grid conditions and other parameters. For example, electronic device 100 can be configured to only prompt the user with available advantageous charging windows if the battery state of charge is below some threshold, e.g., below 50%, and/or if the battery charge is low relative to a typical state of charge for that time of day, suggesting that opportunistic charging might be desirable.

In addition to battery charging, there are other electronic device functions that may be adapted based on grid condition data such as carbon intensity, power cost, available power sources, etc. One example of such function is background processing. Many portable or battery-powered electronic devices may be configured to perform certain tasks as background tasks when the device is connected to an external power source and not when the device is relying on internal battery power. Backups are one example of such a background process that may be preferentially performed only when connected to an external power source. Other such tasks might include analysis of a photo library or other media to perform indexing or similar functionality. Like battery charging, it may be desirable to adjust when or the intensity with which such tasks are performed based on grid conditions of the external power source.

FIG. 7 illustrates a plot 700 of a background processing optimization routine for an electronic device that adapts background processing to grid conditions. FIG. 7 is similar to FIG. 3, and battery charge state curve 710 is provided for continuity. As described above, electronic device 100 can retrieve grid data from which more preferred and less preferred time intervals can be identified. In some cases, a time window may be more preferred or less preferred to a greater degree. For example, more preferred intervals 722 and 724 (lighter shading) may allow for substantially uninhibited background processing. Slightly less preferred intervals 721 (medium shading) may result in the inhibition of some less important background tasks (e.g., software updates) while allowing more important background tasks (e.g., backups) to proceed. Additionally or alternatively, the power allocated to such background processing may be reduced during such an interval to a lesser degree as compared to a substantially less preferred interval 723. Substantially less preferred intervals 723 may result in the inhibition of most or all backup tasks and/or a more substantial reduction in power allocated to background processing. As with the charging optimization adaptations described above, these may be based on any suitable grid data, such as carbon intensity, cost, desired power source availability or unavailability, etc.

As in the charging case discussed above, upon being connected to an external power source, electronic device 100 can estimate a disconnect time 720. Then, the grid data for the plugged in interval may be analyzed to identify less preferred intervals 721/723 and more preferred intervals 722/724 for background processing. Then, as described above background processing may be regulated accordingly during such intervals. FIG. 8 illustrates a flowchart of a background processing adaptation routine 800 for an electronic device that adapts background processing to electrical grid conditions. Background processing adaptation routine 800 may be similar to optimized battery charging routine 400 discussed above with reference to FIG. 4. Thus, the flowchart of FIG. 8 depicts functionality that may be implemented by electronic device 100, including, for example, by processor 101, which may include one or more processors as described above. In some cases, different functions depicted in the flowchart of FIG. 8 may be implemented by different processors of a multi-processor system 100. As but one example, a processor 101 that includes a CPU, a GPU, and a NPU (neural processing unit) may use the NPU to perform certain machine learning computations.

In any case, a grid condition adaptive background processing routine 800 can include a machine learning model and signal processing block 831 that can be used to detect when the electronic device is connected to an external power source and initiate the optimized charging routine as described above. These signals may include the indication of connection to an external power source as well as other signals that allow the processor to identify the power source. For example, a location signal may indicate that the device is at the user's home, workplace, or other frequently visited location, in which case it might be expected that the external power source is mains power. Alternatively, a changing location signal or a speed/velocity sensor may indicate that the device is plugged in to vehicle accessory power source. In some cases, an external power source may provide some other signal that allows it to be identified, as is often the case with wireless power transfer systems. These and other signals may be processed by a machine learning model to attempt to identify the power source and to predict a disconnect time, as indicated by block 832.

As alluded to above, the estimated disconnect time can be derived from the external signals. In cases where the estimated disconnect time provides a sufficient window for optimized background processing, the processor can fetch grid data (block 833) and find desired and/or undesired background processing windows (block 834), which can correspond to the more preferred time intervals 722/724 and less preferred time intervals 721/723 discussed above. As noted above, fetching the grid data in block 833 need not occur immediately upon connecting the device to an external source, but rather can be part of an ongoing process that periodically updates both before and while connected to an external power source so that the grid data is available and/or updated as desired. Once the desired and undesired background processing windows are identified (block 834) the processor can operate to perform or inhibit background processing to the desired degree during such windows, as depicted in block 835. This can include reducing the amount of background processing performed during the undesired intervals or even stopping background processing during the undesired intervals. In some cases, the processor can also communicate information about the charging process and the desired charging windows to the user (block 835). Such communication and optional user interaction can be as discussed above respect to FIG. 6. Additionally, a system for retrieving grid data for optimizing background processing may be as described above with respect to FIG. 5.

As used at various points in this disclosure, machine learning may refer to algorithms, statistical models, and the like that computer systems (such as electronic device 100) can use to perform a specific task with or without using explicit instructions. For example, a machine learning process may generate a mathematical model based on a sample of data, known as “training data,” to make predictions or decisions without being explicitly programmed to perform the task. Depending on the inferences to be made, electronic device 100 (or a sub-system or associated device thereof) may implement different forms of machine learning. For example, in some embodiments (e.g., when particular known examples exist that correlate to future predictions or estimates that the machine learning engine may be tasked with generating), a machine learning engine may implement supervised machine learning. In supervised machine learning, a mathematical model of a set of data contains both inputs and desired outputs. This data is referred to as “training data” and may include a set of training examples. Each training example may have one or more inputs and a desired output, also known as a supervisory signal. In a mathematical model, each training example is represented by an array or vector, sometimes called a feature vector, and the training data is represented by a matrix. Through iterative optimization of an objective function, supervised learning algorithms may learn a function that may be used to predict an output associated with new inputs. An optimal function may allow the algorithm to correctly determine the output for inputs that were not a part of the training data. An algorithm that improves the accuracy of its outputs or predictions over time is said to have learned to perform that task.

Supervised learning algorithms may include classification and regression techniques. Classification algorithms may be used when the outputs are restricted to a limited set of values, and regression algorithms may be used when the outputs have a numerical value within a range. Similarity learning is an area of supervised machine learning closely related to regression and classification, but the goal is to learn from examples using a similarity function that measures how similar or related two objects are. Similarity learning has applications in ranking, recommendation systems, visual identity tracking, face verification, and speaker verification.

Additionally and/or alternatively, in some situations, it may be beneficial for the machine learning engine to utilize unsupervised learning (e.g., when particular output types are not known). Unsupervised learning algorithms take a set of data that contains only inputs, and find structure in the data, like grouping or clustering of data points. The algorithms, therefore, learn from test data that has not been labeled, classified, or categorized. Instead of responding to feedback, unsupervised learning algorithms identify commonalities in the data and react based on the presence or absence of such commonalities in each new piece of data.

That is, the machine learning engine may implement cluster analysis, which is the assignment of a set of observations into subsets (called clusters) so that observations within the same cluster are similar according to one or more predesignated criteria, while observations drawn from different clusters are dissimilar. Different clustering techniques make different assumptions on the structure of the data, often defined by some similarity metric and evaluated, for example, by internal compactness, or the similarity between members of the same cluster, and separation, the difference between clusters. In additional or alternative embodiments, the machine learning engine may implement other machine learning techniques, such as those based on estimated density and graph connectivity.

The foregoing describes exemplary embodiments of shifting certain tasks performed by an electronic device based on grid conditions associated with an external power source connected to the electronic device. Although numerous specific features and various embodiments have been described, it is to be understood that, unless otherwise noted as being mutually exclusive, the various features and embodiments may be combined various permutations in a particular implementation. Thus, the various embodiments described above are provided by way of illustration only and should not be constructed to limit the scope of the disclosure. Various modifications and changes can be made to the principles and embodiments herein without departing from the scope of the disclosure and without departing from the scope of the claims.

The foregoing describes exemplary embodiments of electronic systems that are able to transmit certain information amongst other systems and devices. The present disclosure contemplates this passage of information improves the devices' functionality. Entities implementing the present technology should take care to ensure that, to the extent any sensitive information is used in particular implementations, that well-established privacy policies and/or privacy practices are complied with. In particular, such entities would be expected to implement and consistently apply privacy practices that are generally recognized as meeting or exceeding industry or governmental requirements for maintaining the privacy of users. Implementers should inform users where personally identifiable information is expected to be transmitted and allow users to “opt in” or “opt out” of participation.

Risk can be minimized by limiting the collection of data and deleting data once it is no longer needed. In addition, and when applicable, data de-identification can be used to protect a user's privacy. For example, a device identifier may be partially masked to convey the power characteristics of the device without uniquely identifying the device. De-identification may be facilitated, when appropriate, by removing identifiers, controlling the amount or specificity of data stored (e.g., collecting location data at city level rather than at an address level), controlling how data is stored (e.g., aggregating data across users), and/or other methods such as differential privacy. Robust encryption may also be utilized to reduce the likelihood that communications between devices are intercepted, spoofed, or otherwise subject to tampering.

1. An electronic device comprising a processor programmed to:
detect connection of an external power source to the electronic device;
determine an estimated disconnection time at which the external power source is expected to be disconnected from the electronic device;
analyze power grid data corresponding to the external power source to identify one or more desired background processing intervals and one or more undesired background processing intervals prior to the estimated disconnection time; and
perform background processing during the identified one or more desired battery charging intervals and inhibit background processing during the one or more undesired battery charging intervals.

2. The electronic device of claim 1 wherein the processor is programmed to determine an estimated disconnection time using a machine learning model.

3. The electronic device of claim 1 wherein: the power grid data corresponding to the external power source comprises carbon intensity data, the one or more desired background processing intervals are intervals of lower carbon intensity, and the one or more undesired background processing intervals are intervals of higher carbon intensity.

4. The electronic device of claim 1 wherein: the power grid data corresponding to the external power source comprises cost data, the one or more desired background processing intervals are intervals of lower cost, and the one or more undesired background processing intervals are intervals of higher cost.

5. The electronic device of claim 1 wherein the processor is programmed to inhibit background processing by reducing the amount of background processing during certain undesired background processing intervals.

6. The electronic device of claim 1 wherein the processor is programmed to inhibit background processing by preventing background processing during certain undesired background processing intervals.

7. The electronic device of claim 1 wherein the processor is further programmed to retrieve the power grid data corresponding to the external power source from a grid data server.

8. The electronic device of claim 1 further comprising a display, wherein the processor is further programmed to communicate information about the one or more desired background processing intervals or the one or more undesired background processing intervals to a user via the display.

9. The electronic device of claim 8 further comprising an input device, wherein the processor is further programmed to receive user input regarding background processing via the input device.

10. A method of operating an electronic device, the method performed by a processor of the electronic device and comprising:
detecting connection of an external power source to the electronic device;
determining an estimated disconnection time at which the external power source is expected to be disconnected from the electronic device;
analyzing power grid data corresponding to the external power source to identify one or more undesired background processing intervals prior to the estimated disconnection time; and
inhibiting background processing during the identified one or more desired battery charging intervals.

11. The method of claim 10 wherein the processor is programmed to determine an estimated disconnection time using a machine learning model.

12. The method of claim 10 wherein: the power grid data corresponding to the external power source comprises carbon intensity data, the one or more desired background processing intervals are intervals of lower carbon intensity, and the one or more undesired background processing intervals are intervals of higher carbon intensity.

13. The method of claim 10 wherein: the power grid data corresponding to the external power source comprises cost data, the one or more desired background processing intervals are intervals of lower cost, and the one or more undesired background processing intervals are intervals of higher cost.

14. The method of claim 10 wherein the processor is programmed to inhibit background processing by reducing the amount of background processing during certain undesired background processing intervals.

15. The method of claim 10 wherein the processor is programmed to inhibit background processing by preventing background processing during certain undesired background processing intervals.

16. The method of claim 10 wherein the processor is further programmed to retrieve the power grid data corresponding to the external power source from a grid data server.

17. The method of claim 10 further comprising communicating information about the one or more desired background processing intervals or the one or more undesired background processing intervals to a user via a display of the electronic device.

18. The method of claim 17 further comprising receiving user input regarding background processing via an input device of the electronic device.
